(19) United States
(12) Patent Application Publication
(10) Pub. No.: US 2020/0006405 A1
(43) Pub. Date: Jan. 2, 2020

(54) MANUFACTURING METHOD OF SEMICONDUCTOR THIN FILM TRANSISTOR AND DISPLAY PANEL USING THE SAME

(71) Applicant: Chunghwa Picture Tubes, LTD., Taoyuan City (TW)

(72) Inventors: Hsi-Ming Chang, Taoyuan City (TW); Shin-Chuan Chiang, Taipei City (TW); Yen-Yu Huang, Taoyuan City (TW)

(73) Assignee: Chunghwa Picture Tubes, LTD., Taoyuan City (TW)

(21) Appl. No.: 16/118,475

(22) Filed: Aug. 31, 2018

(30) Foreign Application Priority Data
Jun. 29, 2018 (CN) 201810694014.6

(51) Int. Cl. H01L 27/12; G02F 1/1368; G02F 1/1362

(52) U.S. Cl. CPC H01L 27/1288; H01L 27/1225; G02F 1/1368; G02F 1/136227; H01L 29/7869; G02F 2001/136236; G02F 2001/13685; G02F 2001/136295; G02F 1/136286

(57) ABSTRACT

A manufacturing method of a semiconductor thin film transistor (TFT) and a display panel are provided. According to the manufacturing method, a substrate is provided. A semiconductor pattern is formed on the substrate. A first insulating layer is formed on the substrate and covers the semiconductor pattern. A first metal layer is formed on the first insulating layer, and the first insulating layer is located between the semiconductor pattern and the first metal layer. A half-tone mask photoresist pattern is formed on the first metal layer. The half-tone mask photoresist pattern exposes a portion of the first metal layer. The portion of the first metal layer exposed by the half-tone mask photoresist pattern is removed to form a gate. The gate covers a portion of the semiconductor pattern. A source and a drain are formed on the semiconductor pattern.

### CROSS-REFERENCE TO RELATED APPLICATION

This application claims the priority benefit of China application serial no. 201810694014.6, filed on Jun. 29, 2018. The entirety of the above-mentioned patent application is hereby incorporated by reference herein and made a part of this specification.

### BACKGROUND

### Technical Field

The disclosure relates to a manufacturing method of a semiconductor thin film transistor (TFT) and a display panel; particularly, the disclosure relates to a manufacturing method of a self-aligned semiconductor TFT and a display panel.

### Description of Related Art

The development of liquid crystal display technology has been rather mature so far, and various panel manufacturers compete with each other in terms of quality improvement and cost reduction. Etching technology is an essential part of manufacturing a thin film transistor (TFT). However, when each stacked layer is patterned through performing an etching process, the partial etching area of the stacked layers may be excessively large, such that the loading effects resulting from the etching process are overly significant.

In view of the above, in the process of manufacturing the TFT through applying the etching technology, the etching of some photoresist and the stacked layers covered by the photoresist may be unexpected or incomplete, which poses a negative impact on the quality of the TFT. Besides, the time required by performing the etching process is extended, thus leading to an increase in the manufacturing time, lowering the manufacturing efficiency, and raising the manufacturing costs.

Accordingly, how to improve the etching yield of the TFT during the manufacturing process as well as ensure the good quality of the resultant TFT and reduce the manufacturing costs has become one of the issues to be resolved by the research and development personnel.

### SUMMARY

The disclosure is directed to a manufacturing method of a semiconductor TFT and a display panel, which may improve the manufacturing efficiency of the semiconductor TFT, simplify the manufacturing technology, and reduce the manufacturing costs, so as to ensure good quality of the semiconductor TFT and the display panel.

In an embodiment, a manufacturing method of a semiconductor TFT is provided herein, and the manufacturing method includes following steps. A substrate is provided. A semiconductor pattern is formed on the substrate. A first insulating layer is formed on the substrate, and the first insulating layer covers the semiconductor pattern. A first metal layer is formed on the first insulating layer, and the first insulating layer is located between the semiconductor pattern and the first metal layer. A half-tone mask photoresist pattern is formed on the first metal layer. The half-tone mask photoresist pattern exposes a portion of first metal layer. The portion of the first metal layer exposed by the half-tone mask photoresist pattern is removed to form a gate that covers a portion of the semiconductor pattern. A source and a drain are formed on the semiconductor pattern.

According to an embodiment, a method of forming the semiconductor pattern includes following steps. A semiconductor material layer is formed on the substrate. The semiconductor material layer is patterned to form the semiconductor pattern.

According to an embodiment, a material of the semiconductor material layer is metal oxide.

According to an embodiment, a method of forming the half-tone mask photoresist pattern includes following steps. A photoresist layer is formed on the first metal layer. The photoresist layer is patterned to form a first photoresist pattern, a second photoresist pattern, and a first opening. A thickness of a portion of the first photoresist pattern is greater than a thickness of the second photoresist pattern. The first opening is overlapped with a portion of the semiconductor pattern and exposes a portion of the first metal layer.

According to an embodiment, a method of forming the gate includes following steps. The portion of the first metal layer exposed by the first opening is removed to form the first metal pattern and expose a portion of the first insulating layer. An ashing process is performed on the first photoresist pattern and the second photoresist pattern to remove the second photoresist pattern and form a first thinning photoresist pattern. The first metal pattern not covered by the first thinning photoresist pattern is removed to form the gate. A portion of the semiconductor pattern covered by the gate is defined as a channel region.

According to an embodiment, before the ashing process is performed, the manufacturing method further includes following steps. The portion of the first insulating layer exposed by the first metal pattern is removed to form a first insulating pattern, a gate insulating layer, and a second opening. The second opening exposes a portion of the semiconductor pattern. The first opening is aligned to and overlapped with the second opening. The gate and the gate insulating layer are partially overlapped with the semiconductor pattern and are aligned to and overlapped with the first thinning photoresist pattern.

According to an embodiment, a method of forming the source and the drain includes following steps. A second insulating layer is formed on the substrate, and the second insulating layer covers two ends of the semiconductor pattern at two opposite sides of the channel region, which defines the two ends as a source region and a drain region respectively, and turns the source region and the drain region into conductors. The second insulating layer is patterned to form a second insulating pattern, and the second insulating pattern has a plurality of vias respectively corresponding to the source region and the drain region. A second metal pattern is formed on the second insulating pattern. The second metal pattern includes the source and the drain respectively electrically connected to the corresponding source region and the corresponding drain region through the vias.

According to an embodiment, a method of forming the second insulating layer includes plasma-enhanced chemical vapor deposition (PECVD).

According to an embodiment, a material of the first metal pattern and the second metal pattern includes molybdenum (Mo), aluminum (Al), titanium (Ti), molybdenum alloy, aluminum alloy, or a combination thereof.

In an embodiment, a display panel including the aforesaid pixel array substrate, an opposite substrate, and a display medium layer is provided. The pixel array substrate includes the semiconductor TFT formed by performing the aforesaid manufacturing method and a pixel electrode. The pixel electrode is disposed on the second insulating pattern and electrically connected to the second metal pattern. The opposite substrate is located opposite to the pixel array substrate. The display medium layer is disposed between the pixel array substrate and the opposite substrate.

In light of the foregoing, according to the manufacturing method of the semiconductor TFT provided in one or more exemplary embodiments, the gate, the gate line, and the opening exposing the semiconductor pattern are simultaneously formed by removing a portion of the first metal layer and the first insulating layer. Thereby, another patterning process is not required to form the gate, the gate insulating layer, and the mask of the gate line, so as to improve the manufacturing efficiency, simplify the manufacturing technology, and reduce the manufacturing costs. Besides, through the partial removal of the first insulating layer to expose the semiconductor pattern in the first opening, it is not necessary to etch an excessively large area of the first insulating pattern. Thereby, the loading effects resulting from etching may be lessened, the manufacturing efficiency of the semiconductor TFT may be improved, the manufacturing costs may be lowered, and the resultant semiconductor TFT can have favorable quality.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1, FIG. 2A, FIG. 2B, FIG. 3, FIG. 4, FIG. 5, FIG. 6A, FIG. 6B, FIG. 7, FIG. 8, FIG. 9, FIG. 10, FIG. 11A, FIG. 11B, FIG. 12, FIG. 13A, FIG. 13B, FIG. 14, FIG. 15A, and FIG. 15B are schematic views illustrating a manufacturing method of a TFT according to an embodiment of the invention.

FIG. 16A and FIG. 16B are schematic views illustrating a manufacturing method of a pixel array substrate according to an embodiment of the invention.

FIG. 17 is a schematic side view of a display panel according to an embodiment of the invention.

### DESCRIPTION OF THE EMBODIMENTS

Reference will now be made in detail to the exemplary embodiments of the invention, examples of which are illustrated in accompanying figures. Wherever possible, identical reference numbers are used in figures and descriptions to refer to identical or similar parts.

The invention will be more fully described with reference to the drawings accompanying the embodiments. However, the invention may be embodied in a variety of different forms and should not be limited to the embodiments described herein. In the drawings, the thicknesses of layers and regions may be increased for clarity purposes. The same or similar reference numbers indicate the same or similar elements which will not be repeatedly described in the following paragraphs.

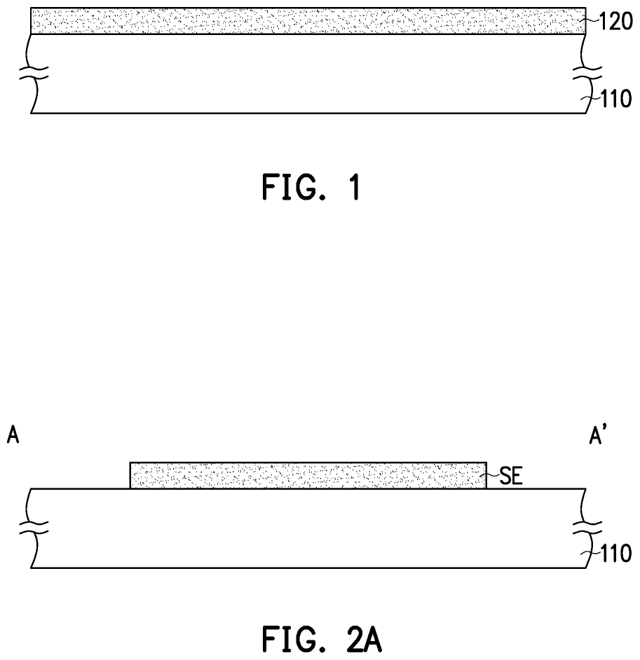

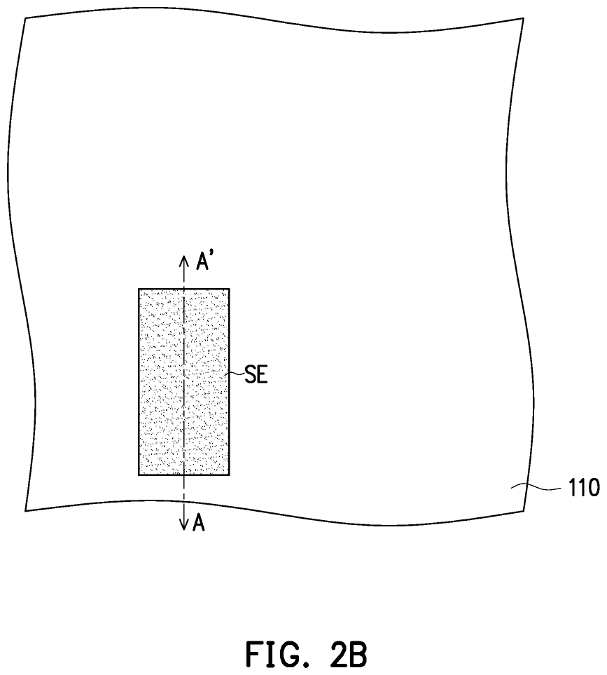

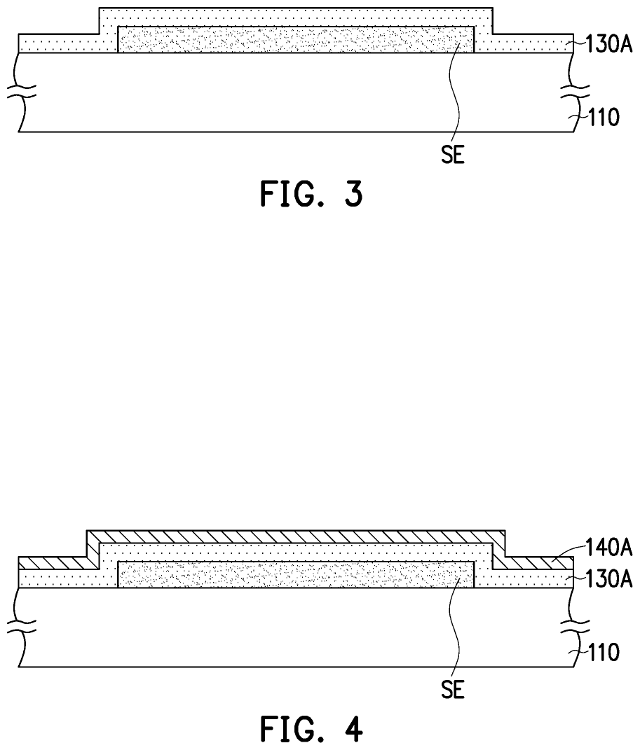

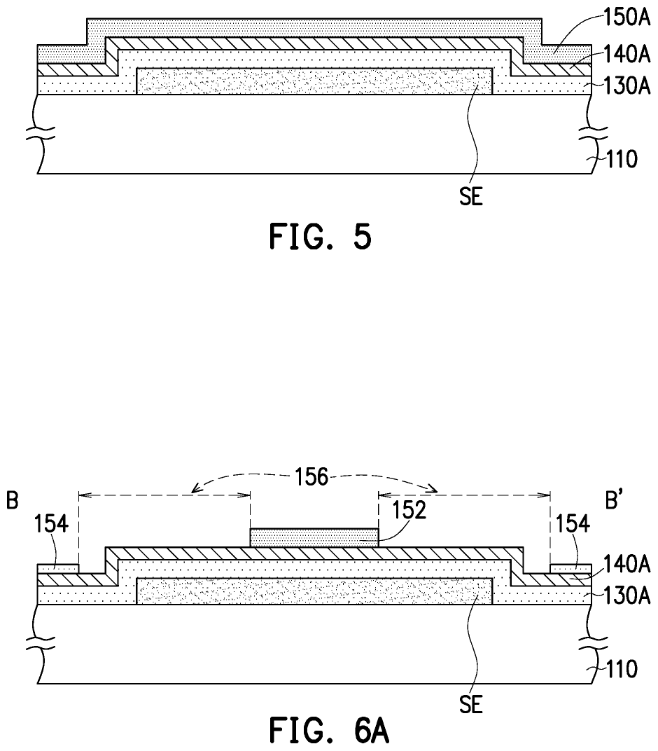

FIG. 1, FIG. 2A, FIG. 2B, FIG. 3, FIG. 4, FIG. 5, FIG. 6A, FIG. 6B, FIG. 7, FIG. 8, FIG. 9, FIG. 10, FIG. 11A, FIG. 11B, FIG. 12, FIG. 13A, FIG. 13B, FIG. 14, FIG. 15A, and FIG. 15B are schematic views illustrating a manufacturing method of a TFT according to an embodiment of the invention. FIG. 2A is a schematic cross-sectional view taken along a sectional line A-A′ in FIG. 2B. FIG. 6A is a schematic cross-sectional view taken along a sectional line B-B′ in FIG. 6B. FIG. 11A is a schematic cross-sectional view taken along a sectional line C-C′ in FIG. 11B. FIG. 13A is a schematic cross-sectional view taken along a sectional line D-D′ in FIG. 13B. FIG. 15A is a schematic cross-sectional view taken along a sectional line E-E′ in FIG. 15B.

With reference to FIG. 1 and FIG. 2A, a substrate 110 is provided, and a semiconductor pattern SE is formed on the substrate 110. Steps of forming the semiconductor pattern SE include a step of forming a semiconductor material layer 120 on the substrate 110, as shown in FIG. 1. The substrate 110 may be a glass substrate, a quartz substrate, or an organic polymer substrate. A material of the semiconductor material layer 120 is metal oxide. In other embodiments, the material of the semiconductor material layer 120 may also be a semiconductor material, such as amorphous silicon, microcrystalline silicon, monocrystalline silicon, an organic semiconductor material, an oxide semiconductor material, or any other appropriate material. The semiconductor material layer 120 may be formed on the substrate 110 through spin coating, slit coating, sputtering, or a combination thereof. For instance, a solution metal oxide semiconductor (SMO) may be coated onto the substrate 110 through slit coating, so as to form the semiconductor material layer 120 on the substrate 110. Thereby, since the SMO is coated onto the substrate 110 having no pattern, it is likely to prevent the issue of uneven film thickness (caused by the flowability of the SMO) while there is a height difference in the pattern (e.g., at the corner of the pattern).

With reference to FIG. 2A and FIG. 2B, the semiconductor material layer 120 is then patterned to form the semiconductor pattern SE. In some embodiments, before the semiconductor material layer 120 is patterned, an annealing process may be selectively performed on the semiconductor material layer 120, so as to improve the crystallinity of the semiconductor material layer 120, which should however not be construed as a limitation in the disclosure. A method of patterning the semiconductor material layer 120 to form the semiconductor pattern SE includes photolithography and etching. Said etching may refer to wet etching, and the etchant applied is, for instance, oxalic acid, aluminic acid, or a combination thereof. In some embodiments, the etchant may further include phosphoric acid, nitric acid, and acetic acid. In other embodiments, it is likely to selectively perform other appropriate processes on the semiconductor pattern SE.

With reference to FIG. 3, a first insulating layer 130A is formed on the substrate 110 and covers the semiconductor pattern SE. In the present embodiment, a material of the first insulating layer 130A may be an inorganic dielectric material, an organic dielectric material, or a combination thereof. For instance, the inorganic material may be silicon oxide, silicon nitride, silicon oxynitride, or a combination thereof, and the organic material may be a polymer material, such as polyimide resin, epoxy resin, or acrylic resin. A method of forming the first insulating layer 130A may be plasma-enhanced chemical vapor deposition (PECVD), spin coating, or a combination thereof.

With reference to FIG. 4, a first metal layer 140A is formed on the first insulating layer 130A, and the first insulating layer 130A is located between the semiconductor pattern SE and the first metal layer 140A. In the present embodiment, the first metal layer 140A is formed on the first insulating layer 130A and covers the semiconductor pattern SE. A material of the first metal layer 140A may be metal, metal oxide, metal nitride, metal oxynitride, or a combination thereof. For instance, the material of the first metal layer 140A may be molybdenum (Mo), aluminum (Al), titanium (Ti), molybdenum alloy, aluminum alloy, or a combination thereof. In the present embodiment, the first metal layer 140A may be formed on the first insulating layer 130A and the semiconductor pattern SE through sputtering, which should not be construed as a limitation in the disclosure; in other embodiments, the first metal layer 140A may be formed in another appropriate manner.

With reference to FIG. 5 and FIG. 6A, a half-tone mask photoresist pattern 150 is then formed on the substrate 110. The half-tone mask photoresist pattern 150 exposes a portion of the first metal layer 140A. Steps of forming the half-tone mask photoresist pattern 150 include a step of forming a photoresist layer 150A on the first metal layer 140A, as shown in FIG. 5.

Next, with reference to FIG. 6A and FIG. 6B, the photoresist layer 150A is patterned to form a first photoresist pattern 152, a second photoresist pattern 154, and a first opening 156. For instance, according to the present embodiment, the photoresist layer 150A formed on the first metal layer 140A may be exposed and developed with use of a half-tone mask (HTM), so that the resultant half-tone mask photoresist pattern 150 is equipped with the first photoresist pattern 152, the second photoresist pattern 154, and the first opening 156. The first opening 156 exposes one portion of the first metal layer 140A. Specifically, the first photoresist pattern 152 covers a location where the gate line and the gate are to be formed subsequently. The second photoresist pattern 154 covers the other portion of the first metal layer 140A not exposed by the first opening 156. In the present embodiment, as shown in FIG. 6A and FIG. 6B, the first opening 156 of the half-tone mask photoresist pattern 150 is overlapped with a portion of the semiconductor pattern SE and exposes one portion of the first metal layer 140A. To clearly show the relative positions of the semiconductor pattern SE and the portion of the first metal layer 140A exposed by the first opening 156, the first insulating layer 130A is not depicted in FIG. 6B.

In the present embodiment, note that a thickness of the first photoresist pattern 152 is greater than a thickness of the second photoresist pattern 154. Thereby, an etching process may be performed with use of one mask to form the photoresist patterns 152 and 154 with different thicknesses and the half-tone mask photoresist pattern 150 having the first opening 156. The half-tone mask photoresist pattern 150 may further define the gate and the gate line as well as provide the self-aligned source and drain in the subsequent etching process, so as to improve the efficiency of the manufacturing process, simplify the manufacturing technology, and lower the manufacturing costs.

With reference to FIG. 6B, FIG. 7, FIG. 8, FIG. 9, and FIG. 10, the portion of the first metal layer 140A exposed by the half-tone mask photoresist pattern 150 is removed to form the gate G, and the gate G covers a portion of the semiconductor pattern SE. With reference to FIG. 7, steps of forming the gate G include a step of removing the portion of the first metal layer 140A exposed by the first opening 156 to form the first metal pattern 140 and a step of exposing a portion of the first insulating layer 130A. In the present embodiment, the first metal layer 140A (e.g., the portion of the first metal layer 140A exposed by the first opening 156) not overlapped with the first photoresist pattern 152 and the second photoresist pattern 154 are removed with use of the half-tone mask photoresist pattern 150 as the mask. That is, the first metal pattern 140 is overlapped with the first photoresist pattern 152 and the second photoresist pattern 154. In some embodiments, a method of removing the portion of the first metal layer 140A exposed by the first opening 156 of the half-tone mask photoresist pattern 150 may be performed through wet etching with use of oxalic acid or aluminic acid as the etchant, so as to expose the underlying first insulating layer 130A.

With reference to FIG. 7 and FIG. 8, before an ashing process is performed on the first photoresist pattern 152 and the second photoresist pattern 154, the portion of the first insulating layer 130A exposed by the first metal pattern 140 is removed, so as to form a first insulating pattern 130, a gate insulating layer GI, and a second opening 132. In the present embodiment, the portion of the first insulating layer 130A exposed by the first opening 156 is removed through wet etching or dry etching, so as to perform a patterning process and form the first opening 156 and the second opening 132 that are aligned to and overlapped with each other. The second opening 132 exposes a portion of the semiconductor pattern SE. For instance, the second opening 132 exposes a portion of the semiconductor pattern SE not covered by the first photoresist pattern 152 or the second photoresist pattern 154. In the present embodiment, the first insulating pattern 130 is overlapped with the first metal pattern 140 and the second photoresist pattern 154. As shown in FIG. 8, the gate insulating layer GI is not overlapped with the second opening 132 but is partially overlapped with the semiconductor pattern SE, and the gate insulating layer GI is aligned to and overlapped with the first photoresist pattern 152. In some embodiments, a method of patterning the first insulating layer 130A may be dry etching with use of a gas containing carbon tetrafluoride (CF₄) and oxygen (O₂).

With reference to FIG. 8 and FIG. 9, an ashing process is performed on the first photoresist pattern 152 and the second photoresist pattern 154 to remove the second photoresist pattern 154 and form a first thinning photoresist pattern 152A. After the second photoresist pattern 154 is removed, the underlying first metal pattern 140 is exposed. In some embodiments, the thickness of the first photoresist pattern 152 is greater than the thickness of the second photoresist pattern 154; hence, the ashing process may be performed on the first photoresist pattern 152 and the second photoresist pattern 154 of the half-tone mask photoresist pattern 150 at the same time, so as to remove the second photoresist pattern 154 and thin down the first photoresist pattern 152. According to the present embodiment, the first photoresist pattern 152 and the first thinning photoresist pattern 152A are substantially the same. As such, the portion of the first metal pattern 140 covered by the first photoresist pattern 152 is still covered by the first thinning photoresist pattern 152A. The other portion of the first metal pattern 140 not covered by the first thinning photoresist pattern 152A (the portion exposed after the second photoresist pattern 154 is removed) is exposed and may be removed through performing a subsequent etching process. Thereby, no additional patterning process is required to form the mask applied for forming the gate G, so as to improve the manufacturing efficiency, simplify the manufacturing technology, and reduce the manufacturing costs.

With reference to FIG. 10, the other portion of the first metal pattern 140 not covered by the first thinning photoresist pattern 152A is removed to form the gate G. In the present embodiment, the other portion of the first metal pattern 140 exposed by the first thinning photoresist pattern 152A is removed with use of the first thinning photoresist pattern 152A as the mask, so as to form the gate G and a gate line GL electrically connected to the gate G (shown in FIG. 11B). As shown in FIG. 10, the gate G and the gate insulating layer GI are partially overlapped with the semiconductor pattern SE and are aligned to and overlapped with the first thinning photoresist pattern 152A. Here, a portion of the semiconductor pattern SE covered by the gate G may be defined as a channel region CH. Thereby, the second opening 132 exposes two ends of the semiconductor pattern SE at two opposite sides of the channel region CH. In said design, the subsequently formed source and drain may be formed on the exposed two sides of the semiconductor pattern SE at the two opposite sides of the channel region CH, so as to achieve the self-alignment effects. According to some embodiments, a method of removing the other portion of the first metal pattern 140 not covered by the first thinning photoresist pattern 152A may be wet etching with use of oxalic acid or aluminic acid as the etchant, and the underlying first insulating pattern 130 is exposed.

With reference to FIG. 11A and FIG. 11B, the first thinning photoresist pattern 152A is removed through ashing, so as to expose the gate G and the gate line GL electrically connected to the gate G. According to the present embodiment, the first insulating pattern 130 is sandwiched between the gate line GL and the substrate. In some embodiments, the gate G and the gate line GL are formed by the same first metal pattern 140. Thereby, as shown in FIG. 6A to FIG. 11B, the first opening 156 and the second opening 132 may be defined by the half-tone mask photoresist pattern 150 as the mask, so as to expose a portion of the semiconductor pattern SE (e.g. the two ends of the semiconductor pattern SE). The thickness of the second photoresist pattern 154 of the half-tone mask photoresist pattern 150 is less than the thickness of the first photoresist pattern 152; hence, the second photoresist pattern 154 may be removed through ashing, and only the first photoresist pattern 152 is thinned down, whereby the exposed portion of first metal pattern 140 is removed with use of the first thinning photoresist pattern 152A as the mask, and the gate G, the gate insulating layer GI, and the gate line GL are further defined. The gate G may also cover a portion of the semiconductor pattern SE to define the channel region CH. Thereby, no additional patterning process is required to form the mask applied for forming the gate G, the gate insulating layer GI, and the gate line GL, so as to improve the manufacturing efficiency, simplify the manufacturing technology, and reduce the manufacturing costs.

It is to be noted, that a portion of the first insulating layer 130A is removed to form the first insulating pattern 130 and the second opening 132, and the semiconductor pattern SE is exposed; thereby, it is not required to remove an excessively large area of the first insulating layer 130A to form the first insulating pattern 130, and the remaining first insulating layer 130A (e.g. the first insulating pattern 130) also is not required to be removed. Thereby, the loading effects resulting from etching may be lessened, the manufacturing efficiency of the semiconductor TFT may be improved, the manufacturing costs may be lowered, and the resultant semiconductor TFT can have favorable quality.

With reference to FIG. 12, FIG. 13A, and FIG. 13B, a source SM and a drain DM are formed on the semiconductor pattern SE. With reference to FIG. 12, steps of forming the source SM and the drain DM include a step of forming a second insulating layer 160A on the substrate 110. Particularly, the second insulating layer 160A covers the two ends of the semiconductor pattern SE at two opposite sides of the channel region CH. In the present embodiment, the second insulating layer 160A is made of silicon nitride, for instance, which should however not be construed as a limitation in the disclosure. A method of forming the second insulating layer 160A includes PECVD.

Here, the second insulating layer 160A is made of silicon nitride supplied with abundance of nitrogen atoms, for instance, and when the second insulating layer 160A is formed through PECVD, the two ends of the semiconductor pattern SE at the two opposite sides of the channel region CH may become a conductor by nitrogen atoms. For instance, the semiconductor pattern SE covered by the second insulating layer 160A may be turned into a conductor and is defined to become a source region S and a drain region D separated from each other by the channel region CH. As such, no additional patterning process is required to form the mask applied for turning the source region S and the drain region D into conductors, so as to achieve the self-alignment of the semiconductor TFT, simplify the manufacturing process, and lower the manufacturing costs. In other embodiments that are not shown in the drawings, when the second insulating layer is made of silicon oxide or any other appropriate material, the exposed semiconductor pattern may be treated by hydrogen first, the second insulating layer is formed through PECVD, and the source region and the drain region are turned into the conductors, which should however not be construed as a limitation in the disclosure.

With reference to FIG. 13A and FIG. 13B, the second insulating layer 160A is patterned to form a second insulating pattern 160. The second insulating pattern 160 has a plurality of vias 162 respectively corresponding to the source region S and the drain region D. In the present embodiment, as shown in FIG. 13A, the vias 162 are respectively overlapped with the source region S and the drain region D, so as to expose the source region S and the drain region D. To clearly show the relative positions of the semiconductor pattern SE and the second insulating pattern 160, the first insulating pattern 130 is not shown in FIG. 13B.

With reference to FIG. 14, a second metal layer 170A is formed on the second insulating pattern 160. The second metal layer 170A fills the vias 162 and is in contact with the source region S and the drain region D. The second metal layer 170A and the first metal layer 140A are made of similar materials, e.g., Mo, Al, Ti, Mo alloy, Al alloy, or a combination thereof. In the present embodiment, the second metal layer 170A may be formed on the second insulating pattern 160 through sputtering, which should however not be construed as a limitation in the disclosure. In other embodiments, the second metal layer 170A may be formed in another appropriate manner.

With reference to FIG. 15A and FIG. 15B, a second metal pattern 170 is formed on the second insulating pattern 160. In the present embodiment, the second metal pattern 170 is formed by patterning the second metal layer 170A. The second metal pattern 170 includes a source SM and a drain DM. The source SM and the drain DM are electrically connected to the corresponding source region S and the corresponding drain region D through the vias 162. That is, the source SM corresponds to the source region S, and the drain DM corresponds to the drain region D. Besides, the second metal pattern 170 further includes a source line SL electrically connected to the source SM. In some embodiments, the source SM and the source line SL are formed by the same second metal pattern 170. In some embodiments, a method of patterning the second metal layer 170A may be performed by removing a portion of the second metal layer 170A through wet etching with use of oxalic acid or aluminic acid as the etchant.

So far, the manufacture of the semiconductor TFT T has been completed. Specifically, the source region S, the drain region D, the gate G, and the channel region CH of the semiconductor pattern SE together constitute the semiconductor TFT T. The semiconductor TFT T may serve as the active device of the display panel. The semiconductor TFT T acting as the active device of a liquid crystal display panel will be described below as an example.

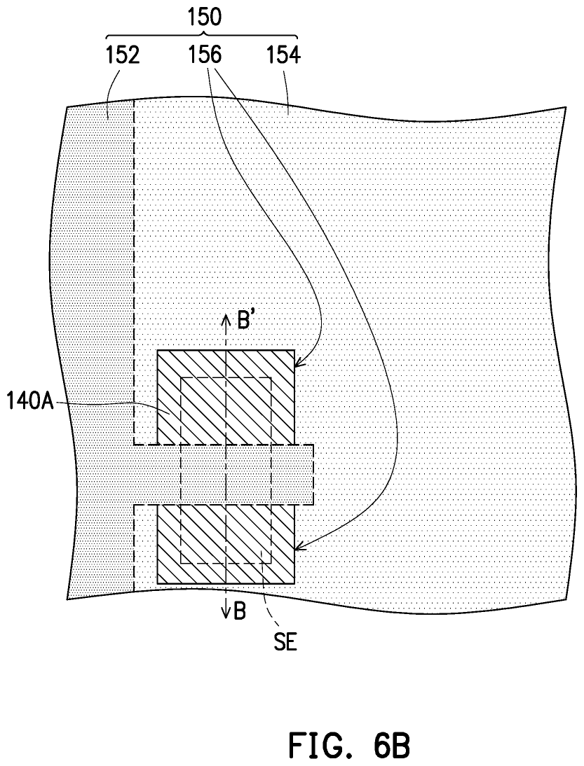

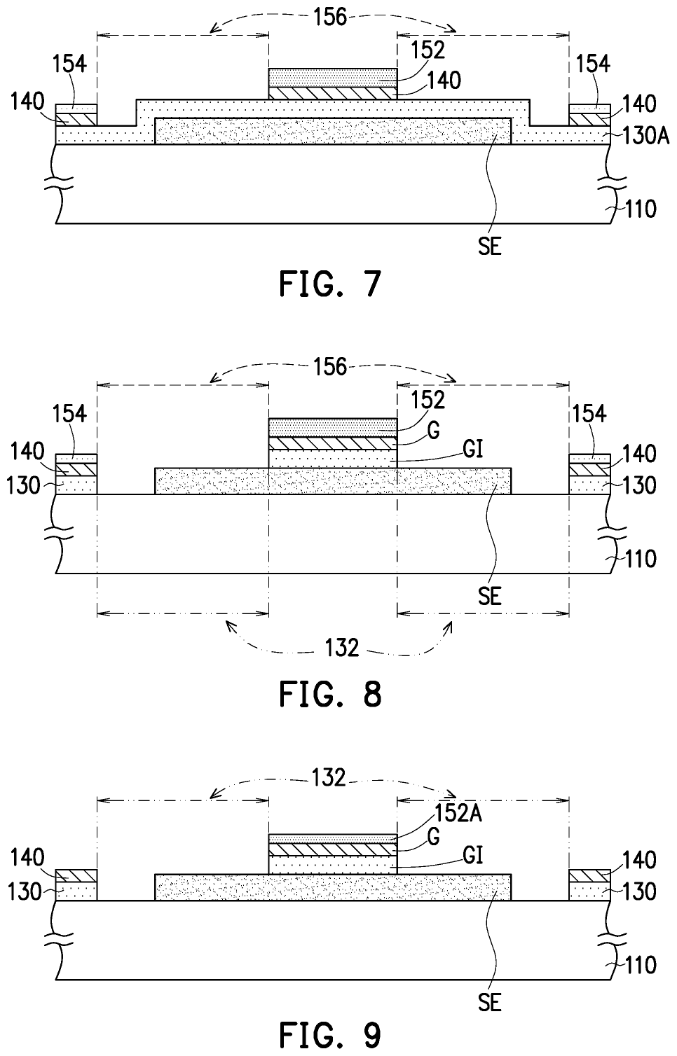

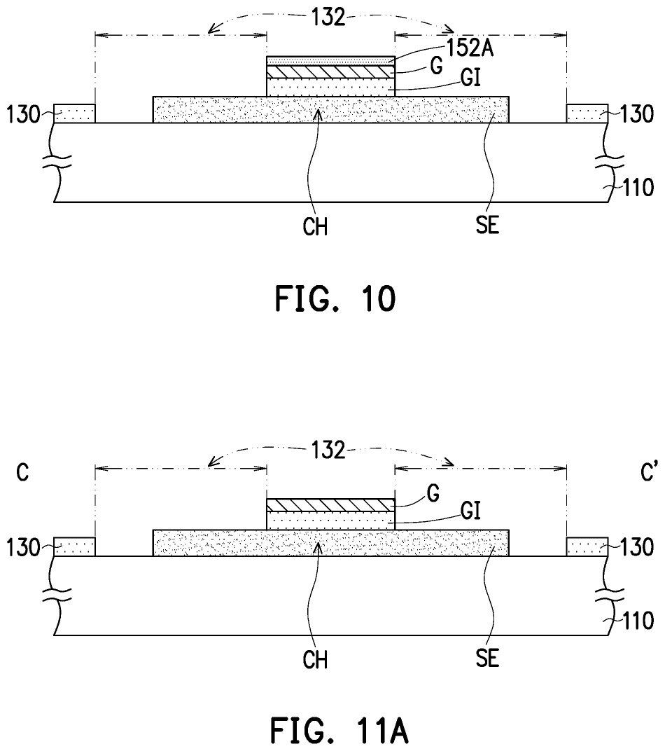

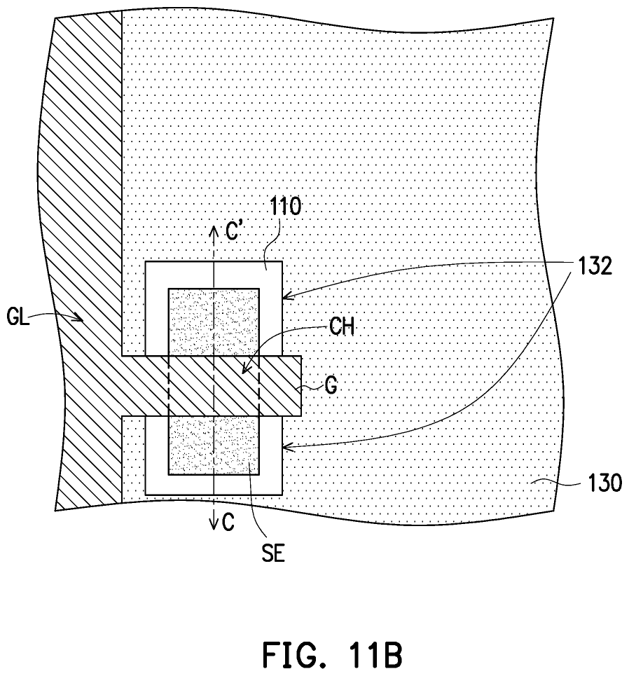

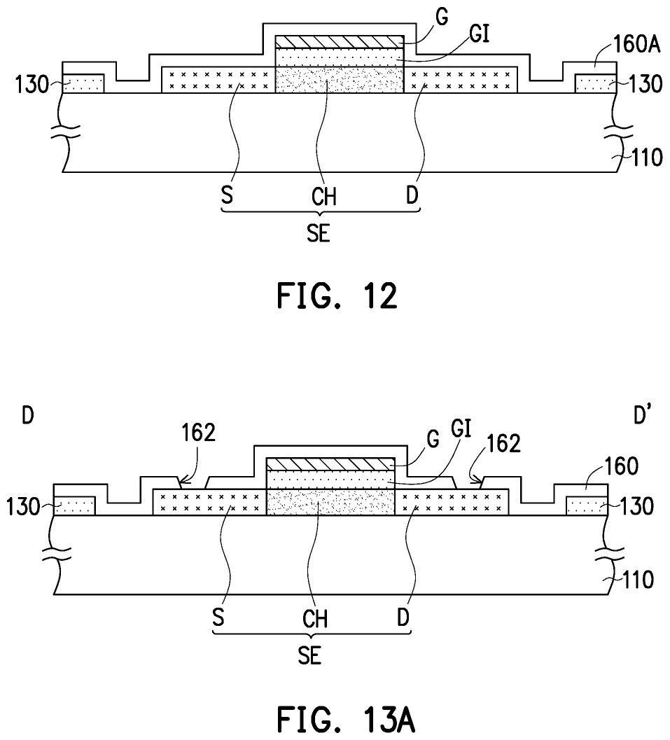

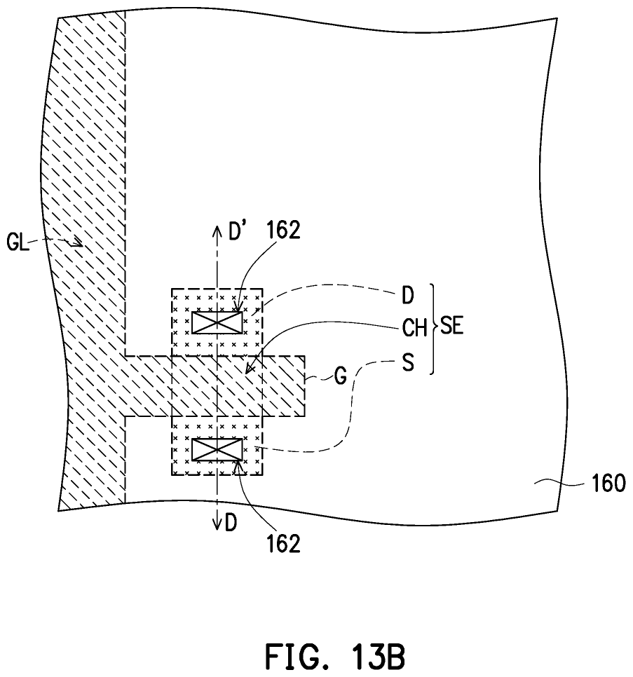

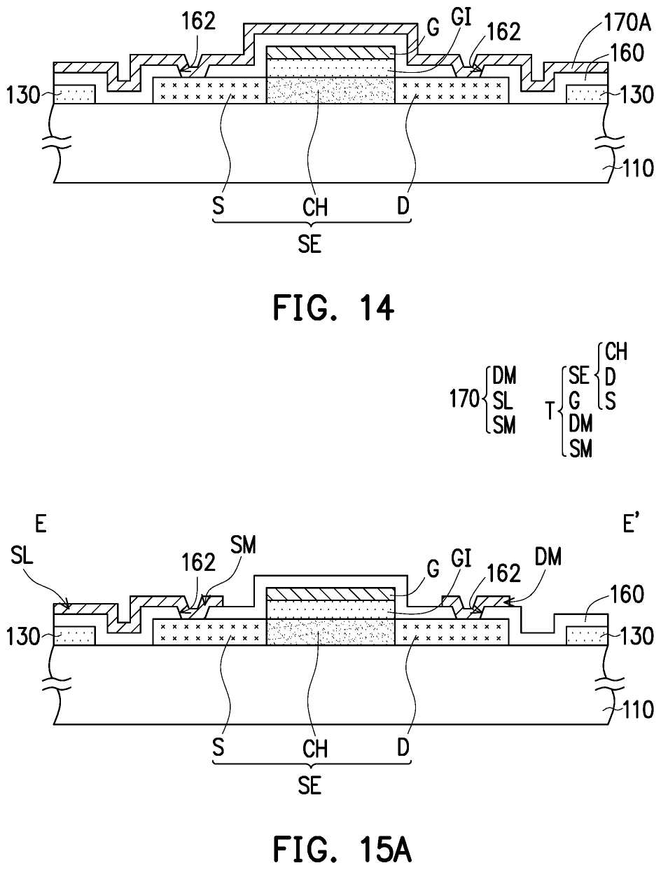

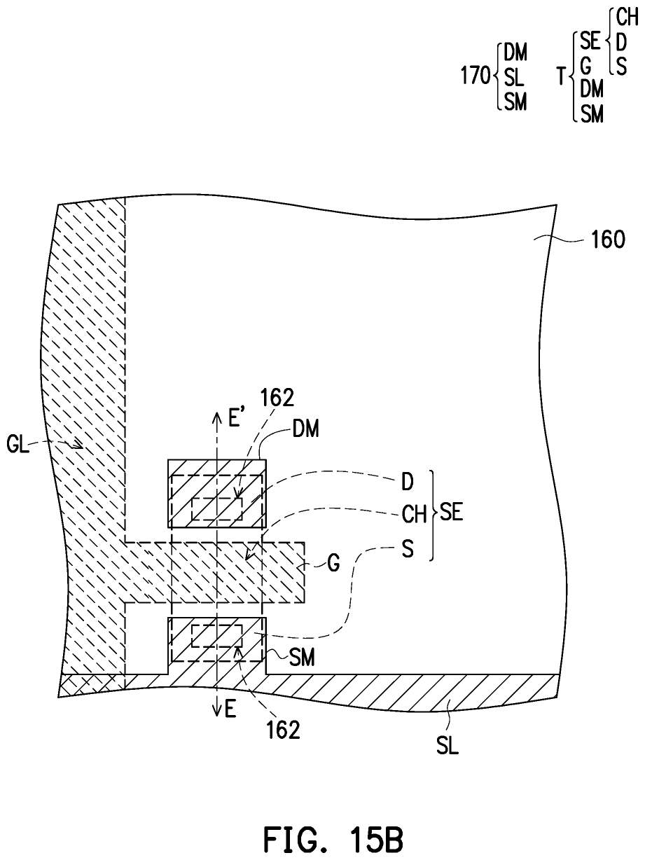

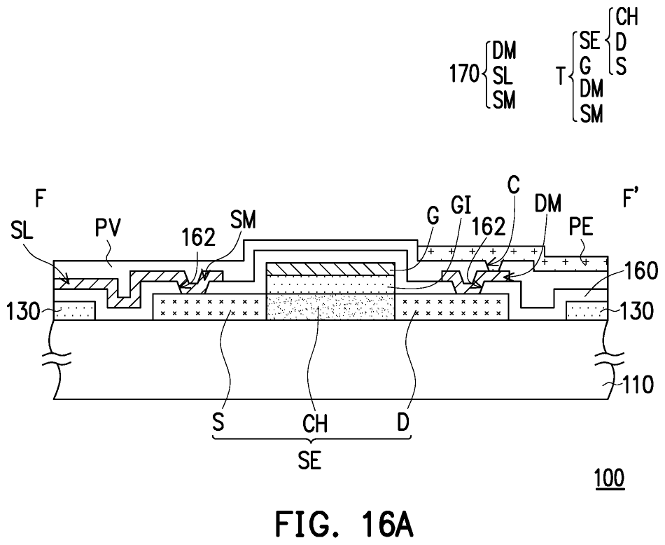

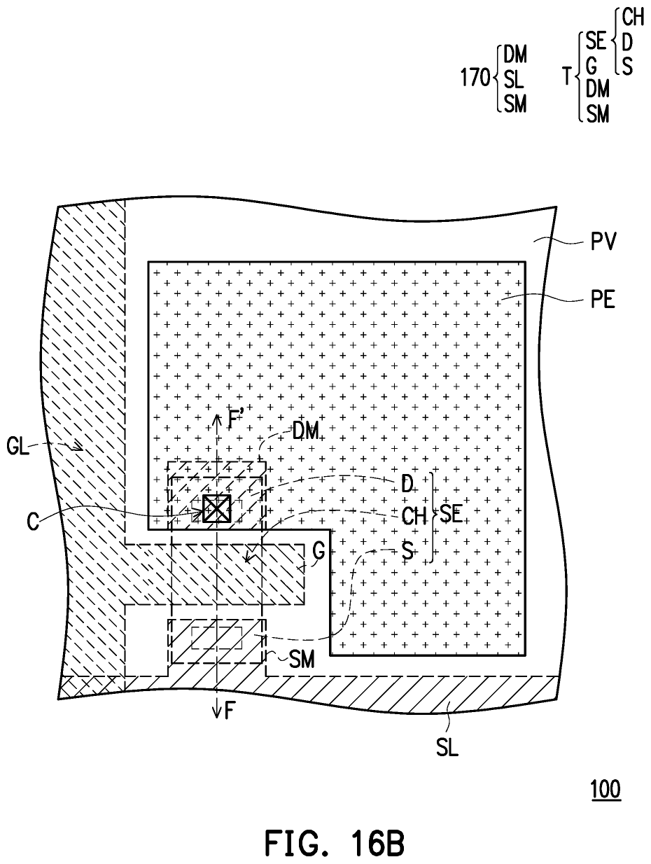

FIG. 16A and FIG. 16B are schematic views illustrating a manufacturing method of a pixel array substrate according to an embodiment of the invention. FIG. 16A is a schematic cross-sectional view taken along a sectional line F-F′ in FIG. 16B. With reference to FIG. 15A and FIG. 16A, according to the present embodiment, a pixel array substrate 100 not only includes the substrate 110, the gate line GL, the source line SL and the semiconductor TFT T but also includes a passivation layer PV and a pixel electrode PE. For instance, after the fabrication of the semiconductor TFT T is completed, the passivation layer PV is formed on the second insulating pattern 160. A material of the passivation layer PV may be an inorganic insulating material, such as silicon oxide, silicon nitride, silicon oxynitride, or a combination thereof. A method of forming the passivation layer may be chemical vapor deposition, atomic layer chemical vapor deposition, or a combination thereof. To clearly show the relative positions of the pixel electrode PE and the passivation layer PV, the first insulating pattern 130 is not shown in FIG. 16B.

With reference to FIG. 16A and FIG. 16B, a contact window C exposing the drain DM is formed in the passivation layer PV. In some embodiments, the contact window C may be filled with a conductive material, e.g., metal, metal oxide, metal nitride, metal oxynitride, or a combination thereof. A method of forming the contact window C may be dry etching with use of a gas containing CF₄ and O₂. The pixel electrode PE is then formed on the passivation layer PV and the second insulating pattern 160, and the pixel electrode PE is electrically connected to the drain DM of the second metal pattern 170 through the contact window C. In the present embodiment, the pixel electrode PE directly fills the contact window C and is electrically connected to the drain DM, which should however not be construed as a limitation in the disclosure. In other embodiments, the pixel electrode PE may be electrically connected to the drain DM through the conductive material filling the contact window C.

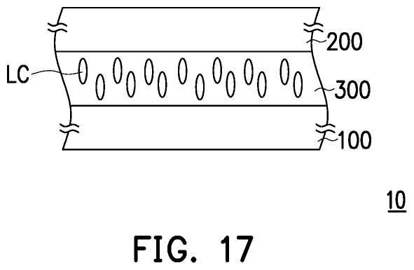

FIG. 17 is a schematic side view of a display panel according to an embodiment of the invention. With reference to FIG. 17, a display panel 10 includes the aforesaid pixel array substrate 100, an opposite substrate 200, and a display medium layer 300. According to the present embodiment, the opposite substrate 200 is located opposite to the pixel array substrate 100. The display medium layer 300 is located between the pixel array substrate 100 and the opposite substrate 200. In the present embodiment, a material of the opposite substrate 200 may be a glass substrate, a quartz substrate, an organic polymer substrate, or any other appropriate material. The display medium layer 300 is composed of liquid crystal molecules, for instance, which should however not be construed as a limitation in the disclosure.

To sum up, in the manufacturing method of the semiconductor TFT provided in one embodiment, the gate, the gate line, and the opening exposing the semiconductor pattern are formed with use of the same mask through removing a portion of the first metal layer and the first insulating layer. Thereby, another patterning process is not required to form the gate, the gate insulating layer, and the mask of the gate line, so as to improve the manufacturing efficiency, simplify the manufacturing technology, and reduce the manufacturing costs. Besides, through the partial removal of the first insulating layer to expose the semiconductor pattern in the first opening, it is not necessary to remove an excessively large area of the first insulating layer and the remains of the first insulating layer that formed the first insulating pattern. Thereby, the loading effects resulting from etching may be lessened, the manufacturing efficiency of the semiconductor TFT may be improved, the manufacturing costs may be lowered, and the resultant semiconductor TFT can have favorable quality. Besides, the channel region and the source region and the drain region located at two opposite sides of the channel region may be defined by the gate. As such, no additional patterning process is required to form the mask applied for turning the source region and the drain region into conductors, so as to achieve the self-alignment of the semiconductor TFT, simplify the manufacturing technology, and lower the manufacturing costs. The display panel equipped with the aforesaid semiconductor TFT can also have favorable quality.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A manufacturing method of a semiconductor thin film transistor, comprising:
providing a substrate;
forming a semiconductor pattern on the substrate;
forming a first insulating layer on the substrate, the first insulating layer covering the semiconductor pattern;
forming a first metal layer on the first insulating layer, the first insulating layer being located between the semiconductor pattern and the first metal layer;
forming a half-tone mask photoresist pattern on the first metal layer, the half-tone mask photoresist pattern exposing a portion of the first metal layer;
removing the portion of the first metal layer exposed by the half-tone mask photoresist pattern to form a gate, the gate covering a portion of the semiconductor pattern; and
forming a source and a drain on the semiconductor pattern.

2. The manufacturing method as recited in claim 1, the step of forming the semiconductor pattern comprising:
forming a semiconductor material layer on the substrate; and
patterning the semiconductor material layer to form the semiconductor pattern.

3. The manufacturing method as recited in claim 2, wherein a material of the semiconductor material layer is metal oxide.

4. The manufacturing method as recited in claim 1, the step of forming the half-tone mask photoresist pattern comprising:
forming a photoresist layer on the first metal layer; and
patterning the photoresist layer to form a first photoresist pattern, a second photoresist pattern, and a first opening,
wherein a thickness of the first photoresist pattern is greater than a thickness of the second photoresist pattern, and the first opening is overlapped with a portion of the semiconductor pattern and exposes a portion of the first metal layer.

5. The manufacturing method as recited in claim 4, the step of forming the gate comprising:
removing the portion of the first metal layer exposed by the first opening to form the first metal pattern and expose a portion of the first insulating layer;
performing an ashing process on the first photoresist pattern and the second photoresist pattern to remove the second photoresist pattern and form a first thinning photoresist pattern; and
removing the first metal pattern not covered by the first thinning photoresist pattern to form the gate,
wherein a portion of the semiconductor pattern covered by the gate is defined as a channel region.

6. The manufacturing method as recited in claim 5, before performing the ashing process, the manufacturing method further comprising:
removing the portion of the first insulating layer exposed by the first metal pattern to form a first insulating pattern, a gate insulating layer, and a second opening, the second opening exposing a portion of the semiconductor pattern,
wherein the first opening is aligned to and overlapped with the second opening, and the gate and the gate insulating layer are partially overlapped with the semiconductor pattern and aligned to and overlapped with the first thinning photoresist pattern.

7. The manufacturing method as recited in claim 6, the step of forming the source and the drain comprising:
forming a second insulating layer on the substrate, the second insulating layer covers two ends of the semiconductor pattern at two opposite sides of the channel region, and defines the two ends as a source region and a drain region and turns the source region and the drain region into conductors;
patterning the second insulating layer to form a second insulating pattern having a plurality of vias respectively corresponding to the source region and the drain region; and
forming a second metal pattern on the second insulating pattern, the second metal pattern comprising the source and the drain electrically connected to the source region and the drain region respectively corresponding to the source and the drain through the plurality of vias.

8. The manufacturing method as recited in claim 7, a method of forming the second insulating layer comprising plasma-enhanced chemical vapor deposition.

9. The manufacturing method as recited in claim 7, wherein a material of the first metal pattern and the second metal pattern comprises molybdenum, aluminum, titanium, molybdenum alloy, aluminum alloy, or a combination thereof.

10. A display panel comprising:
a pixel array substrate comprising:
the semiconductor thin film transistor formed by performing the manufacturing method as recited in any one of claim 1; and
a pixel electrode disposed on the second insulating pattern and electrically connected to the second metal pattern;
an opposite substrate located opposite to the pixel array substrate; and
a display medium layer disposed between the pixel array substrate and the opposite substrate.
